(19) United States
(12) Patent Application Publication
(10) Pub. No.: US 2015/0275356 A1
(43) Pub. Date: Oct. 1, 2015

(54) CLEANING METHOD OF APPARATUS FOR FORMING AMORPHOUS SILICON FILM, AND METHOD AND APPARATUS FOR FORMING AMORPHOUS SILICON FILM

(71) Applicant: TOKYO ELECTRON LIMITED, Tokyo (JP)

(72) Inventor: Mitsuhiro OKADA, Nirasaki City (JP)

(21) Appl. No.: 14/669,952

(22) Filed: Mar. 26, 2015

(30) Foreign Application Priority Data
Mar. 28, 2014 (JP) 2014-068867

(51) Int. Cl. C23C 16/44; C23C 16/24; C23C 16/52; C23C 16/455

(52) U.S. Cl. CPC C23C 16/4405; C23C 16/455; C23C 16/24; C23C 16/52

(57) ABSTRACT

A method of cleaning an apparatus for forming an amorphous silicon film by removing an adhered material from an interior of the apparatus after the amorphous silicon film is formed on a workpiece through supply of a process gas into a reaction chamber of the apparatus includes: removing the adhered material from the interior of the apparatus by supplying the cleaning gas into the reaction chamber; and performing at least one purge process selected from a first purge process of supplying ammonia into the reaction chamber, from which the adhered material has been removed by supplying the cleaning gas into the reaction chamber, and a second purge process of supplying a gas containing hydrogen and oxygen into the reaction chamber, from which the adhered material has been removed by supplying the cleaning gas into the reaction chamber.

### CROSS-REFERENCE TO RELATED APPLICATION

This application claims the benefit of Japanese Patent Application No. 2014-068867, filed on Mar. 28, 2014, in the Japan Patent Office, the disclosure of which is incorporated herein in its entirety by reference.

### TECHNICAL FIELD

The present disclosure relates to a cleaning method of an apparatus for forming an amorphous silicon film, and a method and apparatus for forming an amorphous silicon film.

### BACKGROUND

In a process of manufacturing a semiconductor device and the like, electrodes are formed by embedding a silicon film such as an amorphous silicon film in trenches or hole-shaped recesses (contact holes) formed in an interlayer insulation layer on a silicon substrate.

For example, there is known a method of forming a silicon film, in which a contact hole is formed in an interlayer insulation layer on a silicon substrate, followed by forming a silicon film thereon through chemical vapor deposition (CVD).

In the formation of an amorphous silicon film, with a workpiece, for example, a semiconductor wafer, mounted on a ring boat, the amorphous silicon film is formed on the semiconductor wafer, which in turn is removed from the ring boat and subjected to cleaning using, for example, a fluorine cleaning gas. However, when cleaning with the fluorine cleaning gas is repeatedly performed after film formation, an edge layer of the semiconductor wafer mounted on the ring boat is thickened during film formation, thereby causing deterioration in in-plane uniformity.

### SUMMARY

Some embodiments of the present disclosure provide a cleaning method of an apparatus for forming an amorphous silicon film, which can improve in-plane uniformity, and a method and apparatus for forming an amorphous silicon film.

According to one embodiment of the present disclosure, there is provided a method of cleaning an apparatus for forming an amorphous silicon film by removing an adhered material from an interior of the apparatus after the amorphous silicon film is formed on a workpiece through supply of a process gas into a reaction chamber of the apparatus. The method includes: removing the adhered material from the interior of the apparatus by supplying the cleaning gas into the reaction chamber; and performing at least one purge process selected from a first purge process of supplying ammonia into the reaction chamber, from which the adhered material has been removed by supplying the cleaning gas into the reaction chamber, and a second purge process of supplying a gas containing hydrogen and oxygen into the reaction chamber, from which the adhered material has been removed by supplying the cleaning gas into the reaction chamber.

According to another embodiment of the present disclosure, there is provided a method of forming an amorphous silicon film, comprising: forming an amorphous silicon film on a workpiece; and removing an adhered material from the interior of the apparatus for forming an amorphous silicon film by the aforementioned method.

According to another embodiment of the present disclosure, there is provided an apparatus for forming an amorphous silicon film on a workpiece by supplying a process gas into a reaction chamber in which the workpiece is accommodated. The apparatus includes: a cleaning gas supply unit configured to supply a cleaning gas into the reaction chamber; a purge gas supply unit configured to supply ammonia or a gas containing hydrogen and oxygen into the reaction chamber; and a controller configured to control the cleaning gas supply unit and the purge gas supply unit. The controller removes an adhered material from an interior of the apparatus by controlling the cleaning gas supply unit to supply the cleaning gas into the reaction chamber, and then supplies ammonia or the gas containing hydrogen and oxygen into the reaction chamber by controlling the purge gas supply unit.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a processing apparatus according to one embodiment of the present disclosure.

FIG. 2 is a view showing a configuration of a controller employed in the apparatus shown in FIG. 1.

FIG. 3 is a view illustrating a method of forming an amorphous silicon film according to one embodiment of the present disclosure.

FIG. 4 is a view illustrating a cleaning method of an apparatus for forming amorphous silicon film according to one embodiment of the present disclosure.

FIGS. 5A and 5B are diagrams illustrating effects of ammonia purge.

FIG. 6 is a graph depicting a relationship between film thickness and in-plane uniformity of an amorphous silicon film formed after ammonia purge and nitrogen purge.

FIG. 7 is a view illustrating a cleaning method of an apparatus for forming an amorphous silicon film according to another embodiment of the present disclosure.

FIG. 8 is a view illustrating a cleaning method of an apparatus for forming an amorphous silicon film according to another embodiment of the present disclosure.

FIG. 9 is a view illustrating a cleaning method of an apparatus for forming an amorphous silicon film according to yet another embodiment of the present disclosure.

### DETAILED DESCRIPTION

Hereinafter, a cleaning method of an apparatus for forming an amorphous silicon film, a method for forming an amorphous silicon film, and an apparatus for forming an amorphous silicon film according to some embodiments of the present disclosure will be described. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

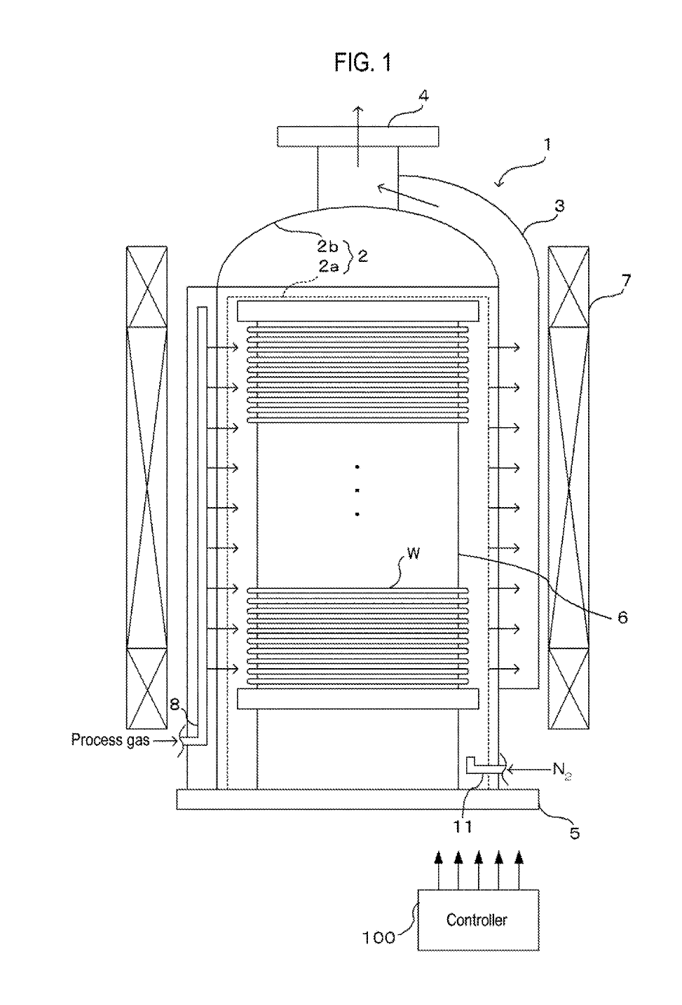

In the following embodiments, a description will be given by way of an example in which a batch-type vertical processing apparatus as shown in FIG. 1 is used as an apparatus for forming an amorphous silicon film.

Referring to FIG. 1, the processing apparatus 1 includes a reaction tube 2 having a longitudinal side which extends in the vertical direction. The reaction tube 2 has a double tube structure which includes an inner tube 2a and a roofed outer tube 2b configured to cover the inner tube 2a and separated a predetermined distance from the inner tube 2a. Sidewalls of the inner tube 2a and the outer tube 2b have a plurality of openings as indicated by arrows in FIG. 1. The inner tube 2a and the outer tube 2b are made of a material having excellent properties in terms of heat resistance and corrosion resistance, for example, quartz.

The reaction tube 2 is provided at one side thereof with an exhaust unit 3 that exhausts gas from the reaction tube 2. The exhaust unit 3 extends upward along the reaction tube 2 and communicates with the reaction tube 2 through the openings formed in the sidewall of the reaction tube 2. The exhaust unit 3 is connected at an upper end thereof to an exhaust port 4 arranged at an upper portion of the reaction tube 2. An exhaust pipe (not shown) is connected to the exhaust port 4. Pressure regulating mechanisms such as a valve (not shown) and a vacuum pump 127 described below are disposed in the exhaust pipe. By virtue of the pressure regulating mechanisms, a gas supplied from one side of the sidewall of the outer tube 2b (a process gas supply pipe 8) is exhausted to the exhaust pipe through the inner tube 2a, the other side sidewall of the outer tube 2b, the exhaust unit 3, and the exhaust port 4. Thus, the interior of the reaction tube 2 is controlled to a desired pressure (vacuum degree).

A lid 5 is disposed under the reaction tube 2. The lid 5 is made of a material having excellent properties in terms of heat resistance and corrosion resistance, for example, quartz. The lid 5 may be moved up and down by a boat elevator 128 described below. When the lid 5 is moved up by the boat elevator 128, a lower end (furnace port) of the reaction tube 2 is closed. When the lid 5 is moved down by the boat elevator 128, the lower end (furnace port) of the reaction tube 2 is open.

A wafer boat 6 is mounted on the lid 5. The wafer boat 6 is made of, for example, quartz. The wafer boat 6 is configured to accommodate a plurality of semiconductor wafers W such that the plural semiconductor wafers W are separated a predetermined distance from each other in the vertical direction. Furthermore, a heat insulating container, which prevents reduction in internal temperature of the reaction tube 2 at the furnace port of the reaction tube 2, or a rotary table, which rotatably accommodates the wafer boat 6 for accommodating the semiconductor wafers W, may be disposed on the lid 5, and the wafer boat 6 may be mounted thereon. In this case, it is easy to uniformly control the temperature of the semiconductor wafers W accommodated within the wafer boat 6.

In the vicinity of the reaction tube 2, heaters 7 formed of, for example, resistive heating elements, are disposed so as to surround the reaction tube 2. The interior of the reaction tube 2 is heated to a predetermined temperature by the heaters 7. As a result, the semiconductor wafers W accommodated within the reaction tube 2 are heated to a predetermined temperature.

The process gas supply pipe 8 for supplying a process gas into the reaction tube 2 (the outer tube 2b) is inserted into the reaction tube 2 through a side surface near the lower end of the reaction tube 2. Examples of the process gas include disilane (Si₂H₆) as a gas for formation of an amorphous silicon film, fluorine (F₂) as a cleaning gas, ammonia (NH₃) as a purge gas, and the like.

A plurality of supply orifices is formed in the process gas supply pipe 8 to be arranged at predetermined intervals in the vertical direction. The process gas is supplied into the reaction tube 2 (the outer tube 2b) through the supply orifices. Thus, as indicated by arrows in FIG. 1, the process gas is supplied into the reaction tube 2 from a plurality of points arranged in the vertical direction.

Further, a nitrogen gas supply pipe 11 for supplying nitrogen (N₂) as a diluting gas and a purge gas into the reaction tube 2 (the outer tube 2b) is inserted into the reaction tube 2 through the side surface near the lower end of the reaction tube 2.

The process gas supply pipe 8 and the nitrogen gas supply pipe 11 are connected to gas supply sources (not shown) through mass flow controllers (MFCs) 125 described below.

A plurality of temperature sensors 122, for example, thermocouples, for measuring the internal temperature of the reaction tube 2, and a plurality of pressure gauges 123 for measuring the internal pressure of the reaction tube 2 are disposed within the reaction tube 2.

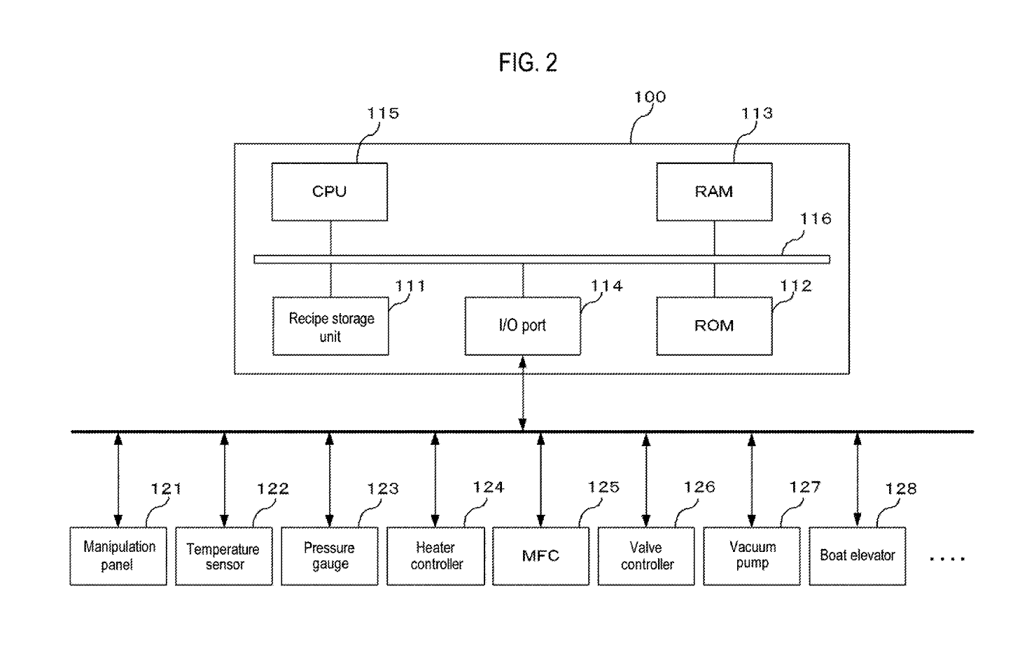

The processing apparatus 1 further includes a controller 100 configured to control the respective components of the apparatus. FIG. 2 shows the configuration of the controller 100. As shown in FIG. 2, a manipulation panel 121, the temperature sensors 122, the pressure gauges 123, a heater controller 124, the MFCs 125, valve controllers 126, the vacuum pump 127, the boat elevator 128 and the like are connected to the controller 100.

The manipulation panel 121, provided with a display and manipulation buttons, transmits operator instructions to the controller 100, and displays a variety of information received from the controller 100 on the display thereof.

The temperature sensors 122 measure the temperatures of the respective components within the reaction tube 2 and within the exhaust pipe, and notify the controller 100 of the measured values.

The pressure gauges 123 measure the pressures of the respective components within the reaction tube 2 and within the exhaust pipe, and notify the controller 100 of the measured values.

The heater controller 124 individually controls the heaters 7. In response to instructions received from the controller 100, the heater controller 124 allows supply of electric current to the heaters 7 to heat the heaters 7. Moreover, the heater controller 124 measures power consumption of the respective heaters 7 and notifies the controller 100 of the measured values.

The respective MFCs 125 are disposed in the respective pipes, that is, in the process gas supply pipe 8 and the nitrogen gas supply pipe 11, to control flow rates of gases flowing through the respective gas supply pipes at rates instructed by the controller 100. In addition, the MFCs 125 measure the actual flow rates of the gases and notify the controller 100 of the measured flow rates.

The valve controllers 126 are disposed in the respective pipes and control the opening degrees of the valves disposed in the respective pipes to be set to the values instructed by the controller 100.

The vacuum pump 127 is connected to the exhaust pipe and exhausts the gas present within the reaction tube 2.

The boat elevator 128 moves the lid 5 upward to load the wafer boat 6 (the semiconductor wafers W) into the reaction tube 2, and moves the lid 5 downward to unload the wafer boat 6 (the semiconductor wafers W) from the interior of the reaction tube 2.

The controller 100 includes a recipe storage unit 111, a read only memory (ROM) 112, a random access memory (RAM) 113, an input/output (I/O) port 114, a central processing unit (CPU) 115, and a bus 116 interconnecting these components to one another.

A setup recipe and a plurality of process recipes are stored in the recipe storage unit 111. In manufacture of the processing apparatus 1, only the setup recipe is stored in the recipe storage unit 111. The setup recipe is executed to generate thermal models and the like for individual processing apparatuses. The process recipe is prepared for each heat treatment (process) actually performed by a user. Each of the process recipes defines temperature changes of the respective components, pressure changes within the reaction tube 2, and supply start/stop timings and supply amounts of various types of gases, during the time period from when the semiconductor wafers W are loaded into the reaction tube 2 to when the processed semiconductor wafers W are unloaded from the reaction tube 2.

The ROM 112 is constituted by an electrically erasable programmable read only memory (EEPROM), a flash memory, a hard disk or the like. The ROM 112 is a recording medium that stores an operation program of the CPU 115.

The RAM 113 serves as a work area of the CPU 115.

The I/O port 114 is connected to the manipulation panel 121, the temperature sensors 122, the pressure gauges 123, the heater controller 124, the MFCs 125, the valve controllers 126, the vacuum pump 127, the boat elevator 128, and the like. The I/O port 114 controls input and output of data and signals.

The CPU 115 constitutes a core of the controller 100 and executes control programs stored in the ROM 112. Further, in response to instructions received through the manipulation panel 121, the CPU 115 controls operation of the processing apparatus 1 according to the recipes (process recipes) stored in the recipe storage unit 111. That is, the CPU 115 allows the temperature sensors 122, the pressure gauges 123 and the MFCs 125 to measure the temperatures, pressures, and flow rates of the respective components within the reaction tube 2 and within the exhaust pipe. Based on the measurement data, the CPU 115 outputs control signals to the heater controller 124, the MFCs 125, the valve controllers 126, the vacuum pump 127 and the like, thereby controlling the respective components in accordance with the process recipes.

The bus 116 delivers information between the respective components.

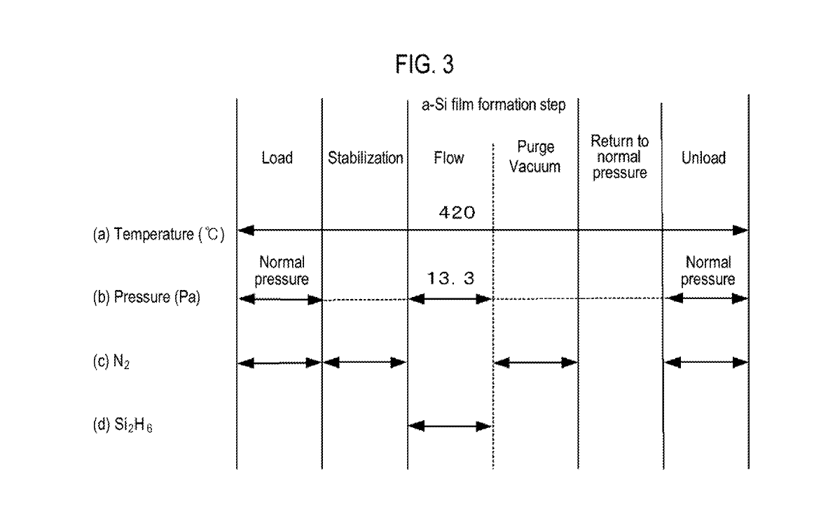

Next, a cleaning method of an apparatus for forming an amorphous silicon film and a method of forming an amorphous silicon film using the processing apparatus 1 configured as above will be described. In the following description, operations of the respective components constituting the processing apparatus 1 are controlled by the controller 100 (the CPU 115). In addition, the controller 100 (the CPU 115) controls the heater controller 124 (the heaters 7), the MFCs 125, the valve controllers 126, and the like in the aforementioned manner, such that the temperature, pressure and flow rates of gases in the reaction tube 2 in the respective processes are set to conditions conforming to, for example, the recipe (time sequence) as shown in FIG. 3. FIG. 3 is a view illustrating a method of forming an amorphous silicon film according to one embodiment of the present disclosure.

First, an inner temperature of the reaction tube 2 is set to a predetermined temperature, for example, 420 degrees C., as shown in (a) of FIG. 3. Further, a predetermined amount of nitrogen is supplied from the nitrogen gas supply pipe 11 into the reaction tube 2, as shown in (c) of FIG. 3. Then, the wafer boat 6 in which a semiconductor wafer W is accommodated is loaded on the lid 5. Then, the lid 5 is moved up by the boat elevator 128 to load the semiconductor wafer W (wafer boat 6) within the reaction tube 2 (loading process).

Next, the interior of the reaction tube 2 is set to a predetermined temperature, for example, 420 degrees C., as shown in (a) of FIG. 3, while a predetermined amount of nitrogen is supplied from the nitrogen gas supply pipe 11 into the reaction tube 2, as shown in (c) of FIG. 3. Further, the reaction tube 2 is evacuated to a predetermined pressure, for example, 13.3 Pa (0.1 Torr), as shown in (b) of FIG. 3. Then, the interior of the reaction tube 2 is stabilized at this temperature and pressure (stabilization process).

The inner temperature of the reaction tube 2 may be in the range of 200 degrees C. to 600 degrees C., or 350 degrees C. to 550 degrees C. Within this range of the inner temperature of the reaction tube 2, it is possible to enhance film quality and thickness uniformity of an amorphous silicon film to be formed on the wafer.

The inner pressure of the reaction tube 2 may be in the range of 0.133 Pa (0.001 Torr) to 13.3 kPa (100 Torr). Within this range of the inner pressure of the reaction tube, it is possible to promote reaction between the semiconductor wafer W and Si. In other embodiments, the inner pressure of the reaction tube 2 is in the range of 6.65 Pa (0.05 Torr) to 1330 Pa (10 Torr). Within this range of the inner pressure of the reaction tube, it is possible to facilitate pressure adjustment within the reaction tube 2.

With the reaction tube 2 stabilized at a predetermined pressure and temperature, supply of nitrogen from the nitrogen gas supply pipe 11 is stopped and a film formation gas is supplied into the reaction tube 2. Specifically, a predetermined amount of disilane (Si₂H₆) is supplied from the process gas supply pipe 8 (flow process), as shown in (d) of FIG. 3 (flow process).

Disilane supplied into the reaction tube 2 is heated and activated within the reaction tube 2. Accordingly, when disilane is supplied into the reaction tube 2, the semiconductor wafer W reacts with activated Si such that a predetermined amount of Si is adsorbed onto the semiconductor wafer W. As a result, an amorphous silicon film is formed on the semiconductor wafer W.

When a predetermined amount of Si is adsorbed onto the semiconductor wafer W, supply of disilane from the process gas supply pipe 8 is stopped. Then, a predetermined amount of nitrogen is supplied from the nitrogen gas supply pipe 11 into the reaction tube 2 to exhaust the gas from the reaction tube 2 (purge/vacuum process), as shown in (c) of FIG. 3.

Further, the inner temperature of the reaction tube 2 is set to a predetermined temperature, for example, 420 degrees C., as shown in (a) of FIG. 3, while a predetermined amount of nitrogen is supplied from the nitrogen gas supply pipe 11 into the reaction tube 2, as shown in (c) of FIG. 3. Further, a predetermined amount of nitrogen is supplied from the nitrogen gas supply pipe 11 into the reaction tube 2 such that the interior of the reaction tube 2 is returned to normal pressure through nitrogen purge (normal pressure restoration process). Then, the lid 5 is moved down by the boat elevator 128 to unload the semiconductor wafer W (unloading process).

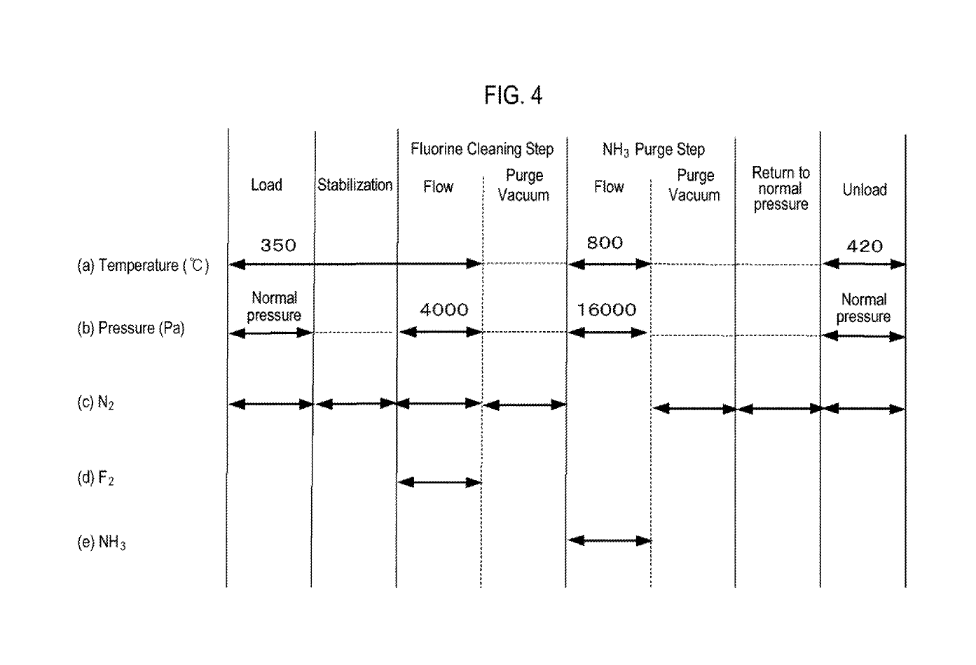

During formation of the amorphous silicon film in this way, the generated reaction products are deposited (adhered) not only to the surface of the semiconductor wafer W but also to an inner surface of the reaction tube 2 or jigs. Accordingly, after formation of the amorphous silicon film, the apparatus for forming an amorphous silicon film is subjected to cleaning. FIG. 4 is a view illustrating a cleaning method of an apparatus for forming amorphous silicon film according to one embodiment of the present disclosure. As shown in FIG. 4, in cleaning of the apparatus for forming an amorphous silicon film, cleaning is first performed with a fluorine cleaning agent, followed by ammonia purge. Hereinafter, the cleaning method of the apparatus for forming an amorphous silicon film according to the embodiment of the present disclosure is described.

First, an inner temperature of the reaction tube 2 is set to a predetermined temperature, for example, 350 degrees C., as shown in (a) of FIG. 4. Further, a predetermined amount of nitrogen is supplied from the nitrogen gas supply pipe 11 into the reaction tube 2, as shown in (c) of FIG. 4. Then, the wafer boat 6 in which a semiconductor wafer W is not accommodated is loaded on the lid 5. Then, the lid 5 is moved up by the boat elevator 128 to load the wafer boat 6 within the reaction tube 2 (loading process).

Next, the interior of the reaction tube 2 is set to a predetermined temperature, for example, 350 degrees C., as shown in (a) of FIG. 4, while a predetermined amount of nitrogen is supplied from the nitrogen gas supply pipe 11 into the reaction tube 2, as shown in (c) of FIG. 4. Further, the reaction tube 2 is evacuated to a predetermined pressure, for example, 4000 Pa (30 Torr), as shown in (b) of FIG. 4. Then, the interior of the reaction tube 2 is stabilized at this temperature and pressure (stabilization process).

The inner temperature of the reaction tube 2 may be in the range of 200 degrees C. to 600 degrees C., or 300 degrees C. to 500 degrees C. Within this range of the inner temperature of the reaction tube 2, it is possible to promote reaction between activated fluorine and adhered materials within the reaction tube 2.

The inner pressure of the reaction tube 2 may be in the range of 0.133 Pa (0.001 Torr) to 13.3 kPa (100 Torr). Within this range of the inner pressure of the reaction tube, it is possible to promote reaction between the activated fluorine and the adhered materials within the reaction tube 2. In other embodiments, the inner pressure of the reaction tube 2 is in the range of 13.3 Pa (0.1 Torr) to 6550 Pa (50 Torr). Within this range of the inner pressure of the reaction tube, it is possible to facilitate pressure adjustment within the reaction tube 2.

With the reaction tube 2 stabilized at a predetermined pressure and temperature, supply of nitrogen from the nitrogen gas supply pipe 11 is stopped and a cleaning gas is supplied into the reaction tube 2. Specifically, a predetermined amount of fluorine (F₂) is supplied from the process gas supply pipe 8 (flow process), as shown in (d) of FIG. 4.

Fluorine supplied into the reaction tube 2 is heated and activated within the reaction tube 2. Thus, when fluorine is supplied into the reaction tube 2, the adhered materials in the reaction tube 2 react with the activated fluorine, whereby the adhered materials can be removed from the reaction tube 2.

After removal of the adhered materials from the reaction tube 2, supply of fluorine from the process gas supply pipe 8 is stopped. Then, a predetermined amount of nitrogen is supplied from the nitrogen gas supply pipe 11 into the reaction tube 2 to exhaust the gas from the reaction tube 2 (purge/vacuum process), as shown in (c) of FIG. 4.

Further, the inner temperature of the reaction tube 2 is set to a predetermined temperature, for example, 800 degrees C., as shown in (a) of FIG. 4, while a predetermined amount of nitrogen is supplied from the nitrogen gas supply pipe 11 into the reaction tube 2, as shown in (c) of FIG. 4. Further, the reaction tube 2 is evacuated to a predetermined pressure, for example, 16000 Pa (120 Torr), as shown in (b) of FIG. 4. Then, the interior of the reaction tube 2 is stabilized at this temperature and pressure.

The inner temperature of the reaction tube 2 may be in the range of 600 degrees C. to 1000 degrees C., or 700 degrees C. to 900 degrees C. Within this range of the inner temperature of the reaction tube, ammonia purge can be efficiently performed through activation of ammonia.

The inner pressure of the reaction tube 2 may be in the range of 0.133 Pa (0.001 Torr) to 65.5 kPa (500 Torr). Within this range of the inner pressure of the reaction tube, ammonia purge can be efficiently performed through activation of ammonia. In other embodiments, the inner pressure of the reaction tube 2 may be in the range of 1330 Pa (10 Torr) to 26.6 kPa (200 Torr). This range of the inner pressure allows easy control of the inner pressure of the reaction tube 2.

With the reaction tube 2 stabilized at a predetermined pressure and temperature, supply of nitrogen from the nitrogen gas supply pipe 11 is stopped and a predetermined amount of ammonia (NH₃) is supplied from the process gas supply pipe 8 into the reaction tube 2 (flow process), as shown in (e) of FIG. 4.

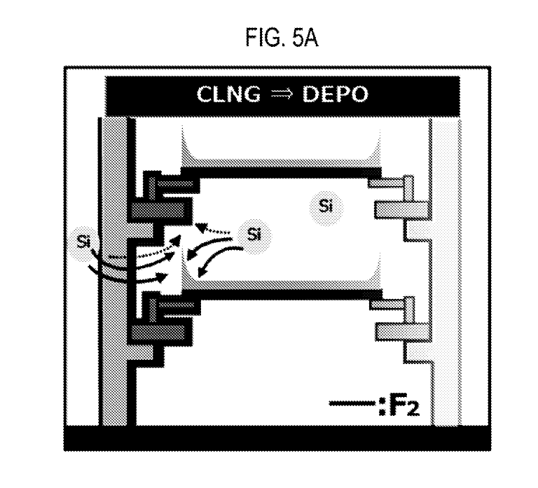

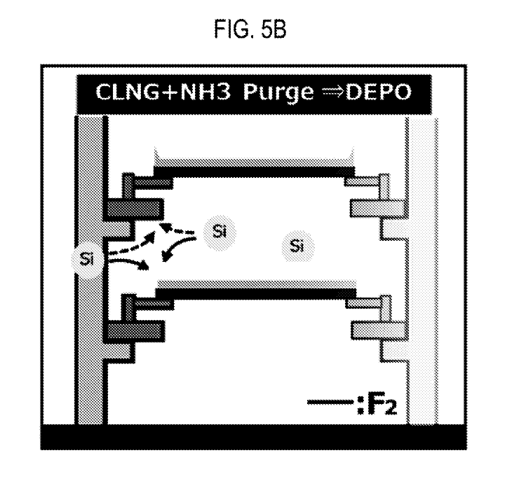

Ammonia supplied into the reaction tube 2 is heated and activated within the reaction tube 2 to react with the remaining fluorine in the reaction tube 2. As a result, it is difficult for amorphous silicon to be deposited on an outer periphery of the semiconductor wafer W in formation of an amorphous silicon film after ammonia purge, thereby improving in-plane uniformity of the amorphous silicon film formed after ammonia purge. FIG. 5A is a diagram of a process of forming an amorphous silicon film without ammonia purge, and FIG. 5B is a diagram of a process of forming an amorphous silicon film without performing ammonia purge after ammonia purge. As shown in FIG. 5B, ammonia purge can prevent a large amount of amorphous silicon from being deposited on the outer periphery of the semiconductor wafer W, thereby improving in-plane uniformity of the amorphous silicon film. This is because incubation time can be controlled by controlling the concentration of fluorine on a surface layer of the ring (wafer boat 6) made of quartz through ammonia purge, thereby enabling control of in-plane uniformity. That is, although the remaining fluorine on the wafer boat 6 delays deposition of the amorphous silicon while promoting deposition of the amorphous silicon around the semiconductor wafer W, ammonia purge promotes deposition of the amorphous silicon onto the wafer boat 6, whereby formation of the amorphous silicon film is suppressed around the semiconductor wafer W, thereby improving in-plane uniformity of the amorphous silicon film in terms of film thickness.

Then, supply of ammonia from the process gas supply pipe 8 is stopped. In addition, a predetermined amount of nitrogen is supplied from the nitrogen gas supply pipe 11 into the reaction tube 2 to exhaust the gas from the reaction tube 2 (purge/vacuum process), as shown in (c) of FIG. 4.

Further, the inner temperature of the reaction tube 2 is set to a predetermined temperature, for example, 420 degrees C., as shown in (a) of FIG. 3, while a predetermined amount of nitrogen is supplied from the nitrogen gas supply pipe 11 into the reaction tube 2, as shown in (c) of FIG. 4. Further, a predetermined amount of nitrogen is supplied from the nitrogen gas supply pipe 11 into the reaction tube 2 such that the interior of the reaction tube 2 is returned to normal pressure through nitrogen purge (normal pressure restoration process). Then, the lid 5 is moved down by the boat elevator 128 to unload the wafer boat 6 (unloading process).

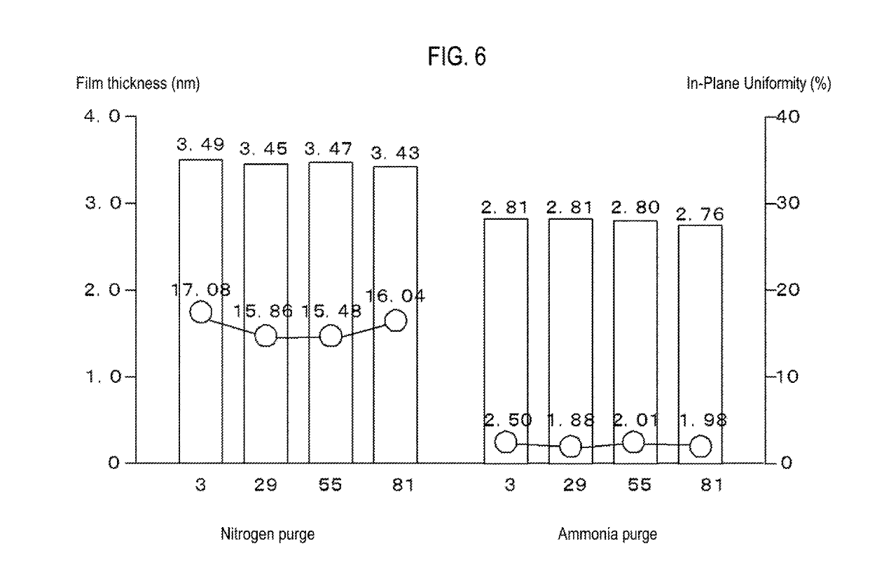

Next, in order to confirm effects of the present disclosure, after cleaning the apparatus for forming an amorphous silicon film by the cleaning method according to the embodiment of the present disclosure, an amorphous silicon film was formed on a semiconductor wafer W, and film thickness and in-plane uniformity of the amorphous silicon film were measured. In addition, for comparison, nitrogen purge was performed instead of ammonia purge in the cleaning method of an apparatus for forming an amorphous silicon film according to the embodiment of the present disclosure, and the film thickness and in-plane uniformity were measured. Results are shown in FIG. 6. Further, in FIG. 6, numerals “3”, “29”, “55”, and “81” indicate locations of semiconductor wafers W on the wafer boat 6, in which [symbol] 3 [symbol] indicates an upper portion of the wafer boat 6, “29” indicates a central upper portion of the wafer boat 6, “55” indicates a central lower portion of the wafer boat 6, and “81” indicates a lower portion of the wafer boat 6. As shown in FIGS. 5A and 5B, it can be confirmed that, when ammonia purge was performed in the cleaning method of an apparatus for forming an amorphous silicon film, the amorphous silicon film had improved in-plane uniformity.

As described above, according to the embodiment of the present disclosure, ammonia purge performed in the cleaning method of the apparatus for forming an amorphous silicon film can improve in-plane uniformity of an amorphous silicon film formed after ammonia purge.

Further, it should be understood that the present disclosure is not limited to the above embodiment and various modifications and alterations can be made. Hereinafter, other embodiments of the present disclosure will be described.

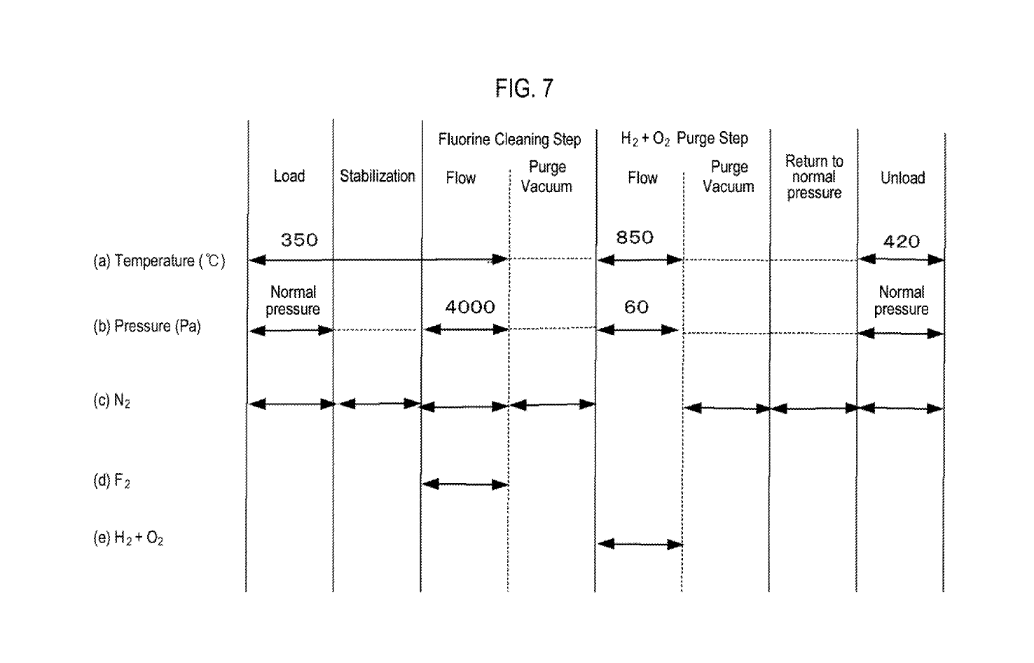

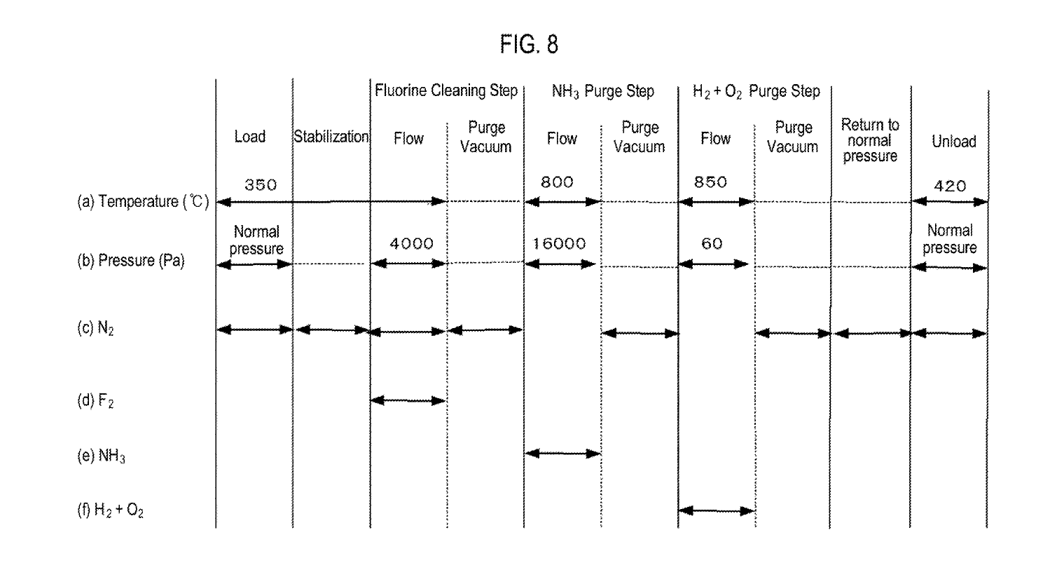

In the aforementioned embodiment, the present disclosure has been described by way of an example wherein a purge operation is performed using ammonia. In alternative embodiments, as shown in FIG. 7, the purge operation may be performed using a gas containing hydrogen (H₂) and oxygen (O₂). Further, as shown in FIG. 8, an additional purge operation may be performed using a gas containing hydrogen (H₂) and oxygen (O₂) after ammonia purge. In any of the cases, incubation time can be controlled by controlling the concentration of fluorine on the surface layer of the ring made of quartz through such purging operation, thereby enabling control of in-plane uniformity of an amorphous silicon film formed thereafter. It is believed that reactive oxygen species are generated by reaction between hydrogen (H₂) and oxygen (O₂), thereby decreasing the concentration of fluorine adhered to the wafer boat 6 and the like.

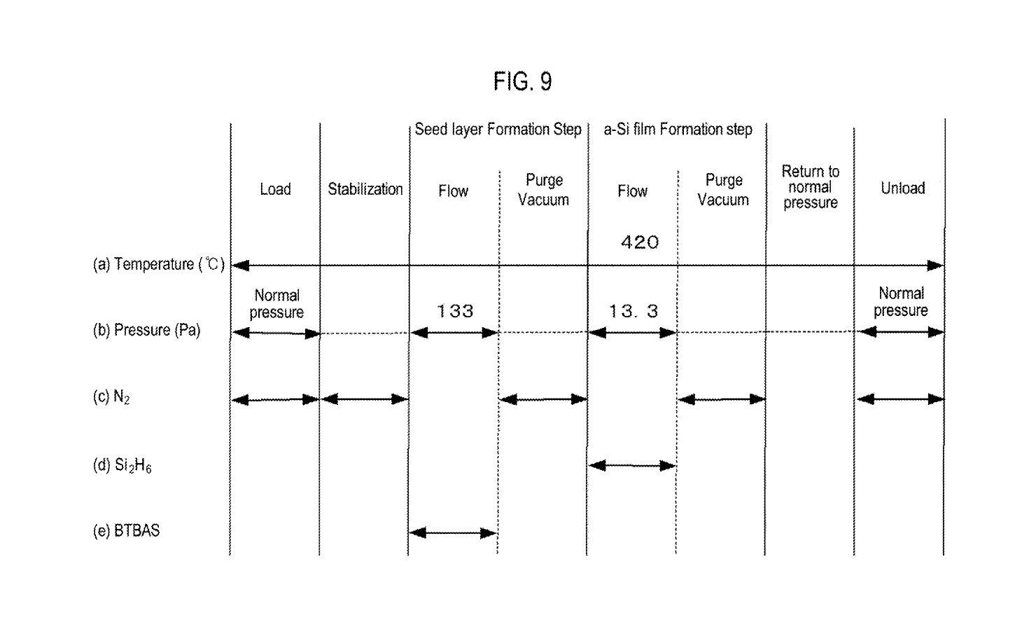

In the aforementioned embodiment, the present disclosure has been described by way of an example wherein the amorphous silicon film is formed using disilane. In alternative embodiments, a seed layer may be formed by adsorbing, for example, aminosilane, and then the amorphous silicon film is formed using disilane, as shown in FIG. 9. In this embodiment, the silicon film has improved film quality (in terms of, for example, in-plane uniformity). Examples of aminosilane used for formation of the seed layer may include butylaminosilane (BAS), bis(tert-butylamino)silane (BTBAS), dimethylaminosilane (DMAS), tris(dimethylamino)silane (TDMAS), diethylaminosilane (DEAS), bis(diethylamino)silane (BDEAS), dipropylaminosilane (DPAS), and diisopropylaminosilane (DIPAS). Alternatively, the seed layer may be formed by adsorbing aminodisilane.

Further, in the aforementioned embodiment, the present disclosure has been described by way of an example wherein the amorphous silicon film is formed using disilane. In alternative embodiments, the amorphous silicon film may be formed using various film formation gases such as monosilane (SiH₄).

In supply of the process gas, the process gas may be supplied alone or may be supplied as a mixture gas of the process gas and nitrogen as a diluting gas. The mixture gas facilitates setting of a process time and the like. The diluting gas may be an inert gas other than nitrogen, for example, helium (He), neon (Ne), argon (Ar), krypton (Kr), or xenon (Xe).

In the aforementioned embodiments, the present disclosure has been described by way of an example wherein the batch-type processing apparatus having a double tube structure is used as the processing apparatus 1. As an alternative example, the present disclosure may also be applied to a batch-type processing apparatus having a single tube structure. Moreover, the present disclosure may be applied to a batch-type horizontal processing apparatus or a single-substrate type processing apparatus.

The controller 100 employed in the embodiments of the present disclosure may be realized using a typical computer system instead of a dedicated computer system. For example, the controller 100 for performing the aforementioned processes may be configured by installing programs for executing processes into a general-purpose computer through a recording medium (a floppy disk, a compact disc-read only memory (CD-ROM), or the like) which stores programs for performing the aforementioned processes.

The programs may be provided by arbitrary means. The programs may be provided not only by the recording medium mentioned above but also through a communication line, a communication network, a communication system or the like. In the latter case, the programs may be posted on bulletin boards (BBSs: Bulletin Board Systems) and provided through a network. The program thus provided is executed in the same manner as other application programs under the control of an operating system (OS), thereby performing the processes described above.

The present disclosure is applicable to a cleaning method of an apparatus for forming an amorphous silicon film, a method of forming an amorphous silicon film, and an apparatus for forming an amorphous silicon film.

According to the present disclosure in some embodiments, it is possible to form a thin film without reduction in film thickness or deterioration in thickness uniformity.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of cleaning an apparatus for forming an amorphous silicon film by removing an adhered material from an interior of the apparatus after the amorphous silicon film is formed on a workpiece through supply of a process gas into a reaction chamber of the apparatus, the method comprising:
removing the adhered material from the interior of the apparatus by supplying the cleaning gas into the reaction chamber; and
performing at least one purge process selected from a first purge process of supplying ammonia into the reaction chamber, from which the adhered material has been removed by supplying the cleaning gas into the reaction chamber, and a second purge process of supplying a gas containing hydrogen and oxygen into the reaction chamber, from which the adhered material has been removed by supplying the cleaning gas into the reaction chamber.

2. The method of claim 1, wherein the cleaning gas comprises fluorine and a concentration of fluorine within the reaction chamber is adjusted in the first purge process and the second purge process.

3. The method of claim 1, wherein, in the first purge process and the second purge process, an inner temperature of the reaction chamber is set in the range of 600 degrees C. to 1000 degrees C.

4. A method of forming an amorphous silicon film, comprising:
forming an amorphous silicon film on a workpiece; and
removing an adhered material from the interior of the apparatus for forming an amorphous silicon film by the method of claim 1.

5. The method of claim 4, wherein the forming the amorphous silicon film comprises forming an amorphous silicon film after adsorbing aminosilane to the workpiece.

6. An apparatus for forming an amorphous silicon film on a workpiece by supplying a process gas into a reaction chamber in which the workpiece is accommodated, the apparatus comprising:
a cleaning gas supply unit configured to supply a cleaning gas into the reaction chamber;
a purge gas supply unit configured to supply ammonia or a gas containing hydrogen and oxygen into the reaction chamber; and
a controller configured to control the cleaning gas supply unit and the purge gas supply unit,
wherein the controller removes an adhered material from an interior of the apparatus by controlling the cleaning gas supply unit to supply the cleaning gas into the reaction chamber, and then supplies ammonia or the gas containing hydrogen and oxygen into the reaction chamber by controlling the purge gas supply unit.
